(19) United States
(12) Patent Application Publication
(10) Pub. No.: US 2020/0136281 A1
(43) Pub. Date: Apr. 30, 2020

(54) LEAD ASSEMBLY AND DISPLAY DEVICE

(71) Applicants: HKC CORPORATION LIMITED, Shenzhen, Guangdong (CN); CHONGQING HKC OPTOELECTRONICS TECHNOLOGY CO.,LTD., Chongqing (CN)

(72) Inventor: Wenxin LI, Chongqing (CN)

(21) Appl. No.: 16/313,406

(22) PCT Filed: Nov. 19, 2018
(86) PCT No.: PCT/CN2018/116122

§ 371 Date: Dec. 26, 2018

(30) Foreign Application Priority Data
Oct. 30, 2018 (CN) 201821778107.9

(51) Int. Cl. H01R 12/52; H05K 1/14; H05K 1/11; H01R 12/55

(52) U.S. Cl. CPC H01R 12/52; H05K 1/144; H05K 2201/10128; H01R 12/55; H05K 1/117

(57) ABSTRACT

A lead assembly and a display panel are disclosed. The lead assembly includes a plurality of leads disposed in a row or in a column, each lead includes a first connection portion, a second connection portion, and a third connection portion that are sequentially connected, a cross sectional area of the second connection portion is smaller than cross sectional areas of the first connection portion and the third connection portion, so that when a cutting line cuts the second connection portion, burrs generated at ends of the first connection portion and the third connection portion can be reduced, and further, defect of a scanning line generated when the first connection portion is connected to a resource driver is alleviated.

### CROSS-REFERENCE TO RELATED APPLICATIONS

This application is the US national stage application of PCT International Application No. PCT/CN2018/116122, which was filed Nov. 19, 2018 and claimed priority to Chinese Patent Application No. 201821778107.9, filed on Oct. 30, 2018. The content of Chinese Patent Application No. 201821778107.9 is incorporated herein by reference.

### BACKGROUND OF THE INVENTION

### Field of the Invention

The present application relates to the technical field of displaying, and in particular, to a lead assembly and a display device.

### Description of Related Art

The description herein provides only background information relates to the present application, but does not necessarily constitute the prior art.

Currently, during panel design, all leads in a bonding area are connected together to enable a panel to be lit up at the forepart of bonding. In this way, a signal is provided at the forepart, so that a screen can also be lit up when not bonded, to help to view some simple images. Subsequently, a cutting line is designed to cut off the bonding leads, and then a bonding procedure is performed. Due to existence of burrs when the cutting line cuts off the bonding leads, the burrs may stab a source driver during bonding, and therefore output of the source driver is abnormal, causing defect of a scanning line (gate horizontal line).

### BRIEF SUMMARY OF THE INVENTION

It is an objective of the present application to provide a lead assembly, to achieve the purpose of, including but not limited to, avoiding defect of a scanning line caused by burrs generated during cutting of leads.

Embodiments of the present application adopt the following technical solutions: a lead assembly, including a plurality of leads disposed in a row or in a column, where each lead includes:

a first connection portion, where one end of the first connection portion is configured to electrically connect to a panel;

a second connection portion, where one end of the second connection portion is connected to the other end of the first connection portion; and

a third connection portion, where one end of the third connection portion is connected to the other end of the second connection portion.

A cross sectional area of the second connection portion is smaller than a cross sectional area of the first connection portion, and is smaller than a cross sectional area of the third connection portion.

In one embodiment, an end face of the first connection portion in connection with the second connection portion is an arc face, and an end face of the third connection portion in connection with the second connection portion is an arc face.

In one embodiment, the end face of the first connection portion in connection with the second connection portion is a circular arc face, and the end face of the third connection portion in connection with the second connection portion is a circular arc face.

In one embodiment, an end face of the first connection portion in connection with the second connection portion is a flat face, and an end face of the third connection portion in connection with the second connection portion is a flat face.

In one embodiment, sections of the first connection portion and the third connection portion in a length direction are oval.

In one embodiment, an end face of the first connection portion in connection with the second connection portion is an arc face, and an end face of the third connection portion in connection with the second connection portion is a flat face.

In one embodiment, an end face of the first connection portion in connection with the second connection portion is a flat face, and an end face of the third connection portion in connection with the second connection portion is an arc face.

In one embodiment, the first connection portion, the second connection portion, and the third connection portion are formed as a whole.

In one embodiment, the first connection portion, the second connection portion, and the third connection portion are formed as a whole and made of a copper material.

In one embodiment, a shape of the second connection portion is a strip shape having a consistent width.

In one embodiment, a shape of the second connection portion is a taper shape having a width gradually increasing from the first connection portion to the third connection portion.

In one embodiment, a length of the second connection portion matches a width of a cutting line configured for cutting the leads.

In one embodiment, the lead assembly further includes a connection line electrically connected to each of the leads.

In one embodiment, the connection line is perpendicularly connected to the leads.

In one embodiment, the connection line is fastened to each of the leads through soldering.

In one embodiment, the connection line is connected to an end of the third connection portion away from the second connection portion.

In one embodiment, the first connection portion, the second connection portion, and the third connection portion are coaxially disposed.

It is another objective of the present application to provide a lead assembly, including a plurality of leads disposed in a row or in a column, where each lead includes:

a first connection portion, where one end of the first connection portion is configured to electrically connect to a panel;

a second connection portion, where one end of the second connection portion is connected to the other end of the first connection portion; and

a third connection portion, where one end of the third connection portion is connected to the other end of the second connection portion, where

a cross sectional area of the second connection portion is smaller than a cross sectional area of the first connection portion, and is smaller than a cross sectional area of the third connection portion, an end face of the first connection portion in connection with the second connection portion is an arc face, and the first connection portion, the second connection portion, and the third connection portion are formed as a whole.

It is still another objective of the present application to provide a display device, including a panel and a source driver, where the panel is connected to the resource driver by using a signal connection line, the signal connection line is formed by a first connection portion after a lead assembly is cut, the lead assembly includes a plurality of leads disposed in a row or in a column, and each lead includes:

a first connection portion, where one end of the first connection portion is configured to electrically connect to the panel;

a second connection portion, where one end of the second connection portion is connected to the other end of the first connection portion; and

a third connection portion, where one end of the third connection portion is connected to the other end of the second connection portion, where

a cross sectional area of the second connection portion is smaller than a cross sectional area of the first connection portion, and is smaller than a cross sectional area of the third connection portion.

The plurality of leads is disposed in a row or in a column on the lead assembly provided in the embodiments of the present application. Each lead includes the first connection portion, the second connection portion, and the third connection portion that are sequentially connected, the first connection portion is configured to electrically connect to the panel, the cross sectional area of the second connection portion is smaller than each of the cross sectional areas of the first connection portion and the third connection portion, so that when the cutting line cuts the second connection portion, burrs generated at ends of the first connection portion and the third connection portion can be reduced, and further, defect of a scanning line generated when the first connection portion is connected to the resource driver is alleviated, thereby improving product yield, and reducing production time. In the display device provided in the embodiments of the present application, the signal connection line configured for the display device is formed by the first connection portion after the lead assembly is cut, to reduce burrs at an end of the signal connection line, and further to alleviate defect of the scanning line, thereby improving the product yield, and reducing the production time.

### BRIEF DESCRIPTION OF THE DRAWINGS

In order to more clearly illustrate the technical solution in embodiments of the present application, the following drawings, which are to be used in the description of the embodiments or the existing techniques, will be briefly described. It will be apparent that the drawings described in the following description are merely embodiments of the present application. Other drawings may be obtained by those skilled in the art without paying creative labor.

FIG. 1 is a schematic structural diagram of a display device according to an embodiment of the present application;

FIG. 2 is a schematic enlarged view of a region A in FIG. 1;

FIG. 3 is a schematic enlarged view of a region B in FIG. 2;

FIG. 4 is a schematic structural diagram of cutting a lead by a cutting line according to an embodiment of the present application;

FIG. 5 is a schematic structural diagram of cutting a lead by a cutting line according to another embodiment of the present application;

FIG. 6 is a schematic structural diagram of cutting a lead by a cutting line according to a comparative embodiment of the present application;

FIG. 7 is a schematic enlarged view of a region C in FIG. 6;

FIG. 8 is a schematic structural diagram of cutting a lead by a cutting line according to still another embodiment of the present application;

FIG. 9 is a schematic structural diagram of cutting a lead by a cutting line according to yet another embodiment of the present application; and

FIG. 10 is a schematic structural diagram of cutting a lead by a cutting line according to still yet another embodiment of the present application.

### LIST OF REFERENCE NUMERALS

10: Lead assembly; 11: Lead; 111: First connection portion; 112: Second connection portion; 113: Third connection portion; 12: Connection line; 13: Cutting line; 14: Burrs; 20: Panel; 30: Resource driver; 31: Connection terminal.

### DETAILED DESCRIPTION OF THE EMBODIMENTS

In order to make the technical problems to be solved, technical solutions, and beneficial effects of the present application more clear, the present application will be further described in detail hereinbelow with reference to the accompanying drawings and embodiments. It should be understood that the specific embodiments described herein are merely intended to explain the application rather than to limit the present application.

It should be noted that when an element is referred to as being “fixed” or “arranged” at/in/on another element, it can be directly at/in/on the other element. When an element is referred to as being “connected” to/with the another element, it can be directly or indirectly connected to/with the other element. It should be understood that terms “top”, “bottom”, “left”, “right”, and the like indicating orientation or positional relationship are based on the orientation or the positional relationship shown in the drawings, and are merely for facilitating the description of the present application, rather than indicating or implying that a device or component must have a particular orientation, or be configured or operated in a particular orientation, and thus should not be construed as limiting the application; and the specific meaning of the above terms can be understood by those skilled in the art according to specific circumstances. Moreover, the terms “first” and “second” are adopted for descriptive purposes only and are not to be construed as indicating or implying a relative importance or implicitly indicating the number of technical features indicated. Thus, features defining “first” and “second” may include one or more of the features either explicitly or implicitly. In the description of the present application, the meaning of “a plurality of” or “multiple” is two or more unless otherwise particularly defined.

The technical solutions of the present application are described in detail below with reference to the accompanying drawings and embodiments.

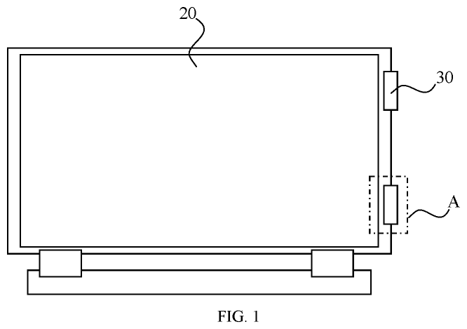

Referring to FIG. 1 to FIG. 3 together, a lead assembly 10 provided in the present application is configured to connect a panel 20 and a resource driver 30 during bonding. In a specific application, a plurality of connection terminals 31 matching the lead assembly 10 is disposed on the resource driver 30, to facilitate bonding.

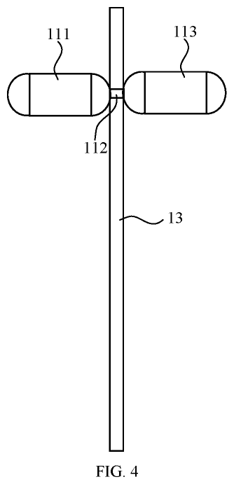

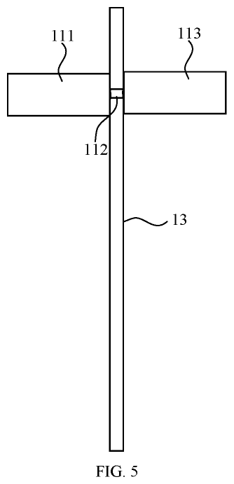

Referring to FIG. 4 and FIG. 5 together, the lead assembly 10 according to an embodiment of the present application is described below. The lead assembly 10 includes a plurality of leads 11 disposed in a row or in a column, and the plurality of leads 11 is disposed parallel to each other. Each lead 11 includes a first connection portion 111, a second connection portion 112, and a third connection portion 113 that are sequentially connected. Specifically, one end of the first connection portion 111 is configured to electrically connect to the panel 20, one end of the second connection portion 112 is connected to the other end of the first connection portion 111, and the other end of the second connection portion 112 is connected to an end of the third connection portion 113. In this embodiment of the present application, a cross sectional area of the second connection portion 112 is smaller than a cross sectional area of the first connection portion 111 as well as a cross sectional area of the third connection portion 113.

In this embodiment of the present application, the plurality of leads 11 is disposed in a row or in a column. Each lead 11 includes the first connection portion 111, the second connection portion 112, and the third connection portion 113 that are sequentially connected, the first connection portion 111 is configured to electrically connect to the panel 20, the cross sectional area of the second connection portion 112 is smaller than each of the cross sectional areas of the first connection portion 111 and the third connection portion 113, so that when a cutting line 13 cuts the second connection portion 112, burrs generated at ends of the first connection portion 111 and the third connection portion 113 can be reduced, and further, defect of a scanning line generated when the first connection portion 111 is connected to the resource driver 30 is alleviated, thereby improving product yield, and reducing production time.

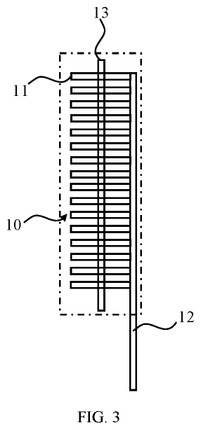

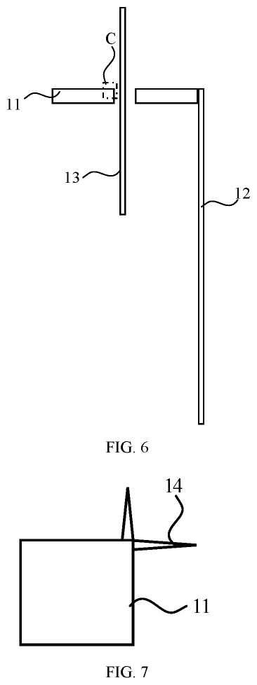

In a comparative embodiment, referring to FIG. 3, each lead 11 is configured to connect the panel 20 and the resource driver 30. During design of the panel 20, all the leads 11 in a bonding area are connected together to enable the panel 20 to be lit up at the forepart of bonding. In this way, a signal is provided at the forepart, so that a screen can also be lit up when not bonded, to help to view some simple images. Subsequently, the cutting line 13 is designed to cut off the bonding leads 11, and then a bonding procedure is performed. In this comparative embodiment, referring to FIG. 6 and FIG. 7 together, a section of the lead 11 in a length direction is rectangular. When the cutting line 13 cuts the lead 11, burrs 14 are generated on a cut end face. The burrs 14 may stab the source driver 30 during bonding, and therefore output of the source driver 30 is abnormal, causing defect of the scanning line.

In one embodiment of the present application, referring to FIG. 4, an end face of the first connection portion 111 in connection with the second connection portion 112 is an arc face, an end face of the third connection portion 113 in connection with the second connection portion 112 is also an arc face, and two ends of the second connection portion 112 are respectively connected to the corresponding arc faces. In this embodiment, when the cutting line 13 cuts the second connection portion 112, burrs 14 on the arc end faces of the first connection portion 111 and the second connection portion 112 can be greatly reduced.

In a specific application, the end face of the first connection portion 111 in connection with the second connection portion 112 is a circular arc face, the end face of the third connection portion 113 in connection with the second connection portion 112 is also a circular arc face, and the two ends of the second connection portion 112 are respectively connected to the corresponding circular arc faces.

In another embodiment of the present application, referring to FIG. 5, an end face of the first connection portion 111 in connection with the second connection portion 112 may alternatively be a plane, and an end face of the third connection portion 113 in connection with the second connection portion 112 may also be a plane, provided that the cross sectional area of the second connection portion 112 is smaller than each of the cross sectional areas of the first connection portion 111 and the third connection portion 113. In this case, compared with the comparative embodiment, the burrs 14 can also be reduced.

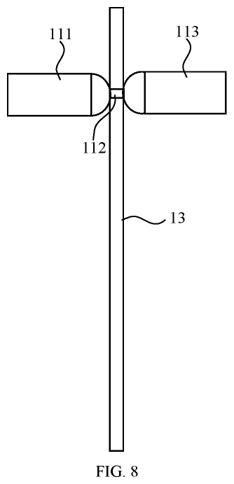

In still another embodiment of the present application, referring to FIG. 8, an end of the first connection portion 111 away from the second connection portion 112 and an end of the third connection portion 113 away from the second connection portion 112 may alternatively be in a form in the comparative embodiment. Reduction of the burrs 14 on the cut end face is not affect, that is, burrs are not generated or increased. In this embodiment, an end of the first connection portion 111 in connection with the second connection portion 112 is a circular arc face, and the end of the first connection portion 111 away from the second connection portion 112 is a flat face. An end of the third connection portion 113 in connection with the second connection portion 112 is a circular arc face, and the end of the third connection portion 113 away from the second connection portion 112 is a flat face.

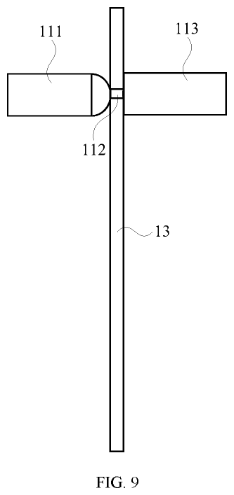

In yet another embodiment of the present application, referring to FIG. 9, an end face of the first connection portion 111 in connection with the second connection portion 112 is an arc face, and an end face of the third connection portion 113 in connection with the second connection portion 112 is a flat face. In this case, burrs at an end of the first connection portion 111 cut by the cutting line 13 are greatly reduced. In this embodiment, an end of the first connection portion 111 away from the second connection portion 112 is a flat face, and an end of the third connection portion 113 away from the second connection portion 112 is also a plane.

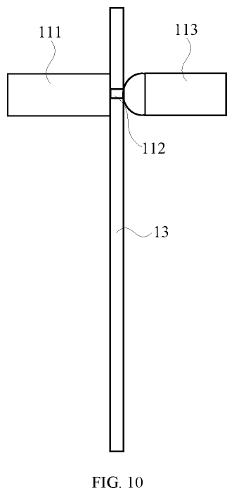

In still yet another embodiment of the present application, referring to FIG. 10, an end face of the first connection portion 111 in connection with the second connection portion 112 is a flat face, and an end face of the third connection portion 113 in connection with the second connection portion 112 is an arc face. In this case, burrs at an end of the third connection portion 113 cut by the cutting line 13 are greatly reduced. In this embodiment, an end of the first connection portion 111 away from the second connection portion 112 is a flat face, and an end of the third connection portion 113 away from the second connection portion 112 is also a plane.

In one embodiment, referring to FIG. 4, sections of the first connection portion 111 and the third connection portion 113 in the length direction are oval, facilitating production and processing. In this embodiment, a section of the second connection portion 112 in the length direction is rectangular. In a specific application, the first connection portion 111 and the third connection portion 113 are symmetrically disposed.

In one embodiment, the first connection portion 111, the second connection portion 112, and the third connection portion 113 are formed as a whole, to help to simplify a structure and reduce costs. In a specific application, the leads are formed as a whole and made of a copper material.

In another embodiment, the first connection portion 111, the second connection portion 112, and the third connection portion 113 may alternatively be separately formed, and then the first connection portion 111, the second connection portion 112, and the third connection portion 113 are sequentially fixedly connected through bonding.

In still another embodiment, the first connection portion 111, the second connection portion 112, and the third connection portion 113 are separately formed, and then the first connection portion 111, the second connection portion 112, and the third connection portion 113 are sequentially fixedly connected through soldering.

In one embodiment, a shape of the second connection portion is a strip shape having a consistent width, to help to simplify a processing process. In a specific application, the width of the second connection portion may be determined according to an actual case. In another embodiment, the shape of the second connection portion is a taper having a width gradually increasing from the first connection portion to the third connection portion. Alternatively, the shape of the second connection portion is a taper having a width gradually increasing from the third connection portion to the first connection portion.

In one embodiment, referring to FIG. 4, FIG. 5, and FIG. 8 together, a length of the second connection portion 112 matches a width of the cutting line 13 configured for cutting the leads 11, that is, the length of the second connection portion 112 is equal to the width of the cutting line 13. The cutting line 13 exactly cuts off the second connection portion 112 during cutting, so that the end faces of the first connection portion 111 and the third connection portion 113 exactly overlap cut faces, to better reduce the burrs 14. In another embodiment, the length of the second connection portion 112 may alternatively be slightly greater than the width of the cutting line 13.

In one embodiment, referring to FIG. 3 and FIG. 6 together, the lead assembly 10 further includes a connection line 12 electrically connected to each of the leads 11. In this embodiment, the connection line 12 is disposed to help to assemble the lead assembly 10 before bonding. In this way, a signal is provided on the connection line 12, so that a screen can also be lit up when not bonded, to help to view some simple images. In a specific application, the connection line 12 is perpendicularly connected to the leads 11, and the connection line 12 may be fastened to each lead 11 through soldering.

In one embodiment, the connection line 12 is connected to the end of the third connection portion 113 away from the second connection portion 112, to prevent the connection line 12 from affecting cutting by the cutting line 13. In this embodiment, after cutting by the cutting line 13, an end of the first connection portion 111 away from the panel 20 is configured to connect to the resource driver 30, and the third connection portion 113 and the connection line 12 may be discarded or configured for other purposes.

In one embodiment, referring to FIG. 4, FIG. 5, and FIG. 8 together, the first connection portion 111, the second connection portion 112, and the third connection portion 113 are coaxially disposed. In this embodiment, the second connection portion 112 is connected to a middle position between the first connection portion 111 and the third connection portion 113, to better reduce the burrs 14 after cutting.

It should be noted that in another embodiment of the present application, when the third connection portion 113 is discarded after being cut, burrs 14 generated on the end face of the third connection portion 113 in connection with the second connection portion 112 during cutting may not be considered. Therefore, the third connection portion 113 may be of a structure in the comparative embodiment.

In addition, in this embodiment of the present application, a specific size of a cross section of the second connection portion 112 may be selected according to an actual case, provided that the specific size is smaller than sizes of cross sections of the first connection portion 111 and the third connection portion 113 and satisfies a requirement on connection to the first connection portion 111 and the third connection portion 113. When a process condition can be achieved, a smaller size of the cross section of the second connection portion 112 is preferred.

Referring to FIG. 4 and FIG. 8 together, an embodiment of the present application further provides a lead assembly 10, and the lead assembly 10 includes a plurality of leads 11 disposed in a row or in a column. The plurality of leads 11 is disposed parallel to each other. Each lead 11 includes a first connection portion 111, a second connection portion 112, and a third connection portion 113 that are sequentially connected. Specifically, one end of the first connection portion 111 is configured to electrically connect to the panel 20, one end of the second connection portion 112 is connected to the other end of the first connection portion 111, and the other end of the second connection portion 112 is connected to an end of the third connection portion 113. A cross sectional area of the second connection portion 112 is smaller than a cross sectional area of the first connection portion 111 as well as a cross sectional area of the third connection portion 113, an end face of the first connection portion 111 in connection with the second connection portion 112 is an arc face, and the first connection portion 111, the second connection portion 112, and the third connection portion 113 are formed as a whole.

In this embodiment of the present application, the plurality of leads 11 is disposed in a row or in a column. Each lead 11 includes the first connection portion 111, the second connection portion 112, and the third connection portion 113 that are sequentially connected, the first connection portion 111 is configured to electrically connect to the panel 20, the cross sectional area of the second connection portion 112 is smaller than each of the cross sectional areas of the first connection portion 111 and the third connection portion 113. The end face of the first connection portion 111 in connection with the second connection portion 112 is an arc face, so that when a cutting line 13 cuts the second connection portion 112, burrs generated at ends of the first connection portion 111 and the third connection portion 113 can be greatly reduced, and further, defect of a scanning line generated when the first connection portion 111 is connected to a resource driver 30 is alleviated, thereby improving product yield, and reducing production time. In addition, the first connection portion 111, the second connection portion 112, and the third connection portion 113 are formed as a whole, to help to simplify a structure and reduce costs.

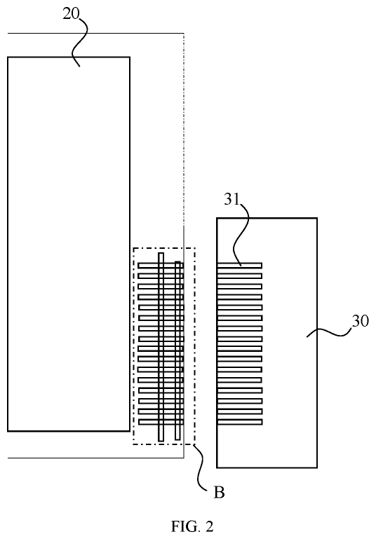

Referring to FIG. 1 and FIG. 2, an embodiment of the present application further provides a display device, including a panel 20 and a resource driver 30. The resource driver 30 is disposed at an edge of the panel 20, the panel 20 is connected to the resource driver 30 by using a signal connection line, and the signal connection line is formed by the first connection portion 111 after the lead assembly 10 is cut.

In the display device provided in this embodiment of the present application, the signal connection line configured for the display device is formed by the first connection portion 111 after the lead assembly 10 is cut, to reduce burrs at an end of the signal connection line, and further to alleviate defect of a scanning line, thereby improving product yield, and reducing production time.

The above description is only optional embodiments of the present application, and is not intended to limit the present application. Any modifications, equivalent substitutions, and improvements made within the spirit and principles of the present application are included in the protection scope of the present application.

What is claimed is:

1. A lead assembly, comprising a plurality of leads disposed in a row or in a column, wherein each lead comprises:
a first connection portion, wherein one end of the first connection portion is configured to electrically connect to a panel;
a second connection portion, wherein one end of the second connection portion is connected to the other end of the first connection portion; and
a third connection portion, wherein one end of the third connection portion is connected to the other end of the second connection portion;
wherein a cross sectional area of the second connection portion is smaller than a cross sectional area of the first connection portion, and is smaller than a cross sectional area of the third connection portion.

2. The lead assembly according to claim 1, wherein an end face of the first connection portion in connection with the second connection portion is an arc face, and an end face of the third connection portion in connection with the second connection portion is an arc face.

3. The lead assembly according to claim 2, wherein the end face of the first connection portion in connection with the second connection portion is a circular arc face, and the end face of the third connection portion in connection with the second connection portion is a circular arc face.

4. The lead assembly according to claim 1, wherein an end face of the first connection portion in connection with the second connection portion is a flat face, and an end face of the third connection portion in connection with the second connection portion is a flat face.

5. The lead assembly according to claim 2, wherein sections of the first connection portion and the third connection portion in a length direction are oval.

6. The lead assembly according to claim 1, wherein an end face of the first connection portion in connection with the second connection portion is an arc face, and an end face of the third connection portion in connection with the second connection portion is a flat face.

7. The lead assembly according to claim 1, wherein an end face of the first connection portion in connection with the second connection portion is a flat face, and an end face of the third connection portion in connection with the second connection portion is an arc face.

8. The lead assembly according to claim 1, wherein the first connection portion, the second connection portion, and the third connection portion are formed as a whole.

9. The lead assembly according to claim 8, wherein the first connection portion, the second connection portion, and the third connection portion are formed as a whole and made of a copper material.

10. The lead assembly according to claim 1, wherein a shape of the second connection portion is a strip shape having a consistent width.

11. The lead assembly according to claim 1, wherein a shape of the second connection portion is a taper shape having a width gradually increasing from the first connection portion to the third connection portion.

12. The lead assembly according to claim 1, wherein a length of the second connection portion matches a width of a cutting line configured for cutting the leads.

13. The lead assembly according to claim 1, wherein the lead assembly further comprises a connection line electrically connected to each of the leads.

14. The lead assembly according to claim 13, wherein the connection line is perpendicularly connected to the leads.

15. The lead assembly according to claim 13, wherein the connection line is fastened to each of the leads through soldering.

16. The lead assembly according to claim 13, wherein the connection line is connected to an end of the third connection portion away from the second connection portion.

17. The lead assembly according to claim 1, wherein the first connection portion, the second connection portion, and the third connection portion are coaxially disposed.

18. A lead assembly, comprising a plurality of leads disposed in a row or in a column, wherein each lead comprises:
a first connection portion, wherein one end of the first connection portion is configured to electrically connect to a panel;
a second connection portion, wherein one end of the second connection portion is connected to the other end of the first connection portion; and
a third connection portion, wherein one end of the third connection portion is connected to the other end of the second connection portion;
wherein a cross sectional area of the second connection portion is smaller than a cross sectional area of the first connection portion, and is smaller than a cross sectional area of the third connection portion, an end face of the first connection portion in connection with the second connection portion is an arc face, and the first connection portion, the second connection portion, and the third connection portion are formed as a whole.

19. A display device, comprising a panel and a source driver, wherein the panel is connected to the resource driver by using a signal connection line, the signal connection line is formed by a first connection portion after a lead assembly is cut, the lead assembly comprises a plurality of leads disposed in a row or in a column, and each lead comprises:
a first connection portion, wherein one end of the first connection portion is configured to electrically connect to the panel;
a second connection portion, wherein one end of the second connection portion is connected to the other end of the first connection portion; and
a third connection portion, wherein one end of the third connection portion is connected to the other end of the second connection portion;
wherein a cross sectional area of the second connection portion is smaller than a cross sectional area of the first connection portion, and is smaller than a cross sectional area of the third connection portion.
